(19) United States
(12) Patent Application Publication
(10) Pub. No.: US 2013/0038344 A1
(43) Pub. Date: Feb. 14, 2013

(54) PROBE ASSEMBLY

(71) Applicant: SHIH-YI CHEN, Tu-Cheng (TW)

(72) Inventor: SHIH-YI CHEN, Tu-Cheng (TW)

(73) Assignee: HON HAI PRECISION INDUSTRY CO., LTD., Tu-Cheng (TW)

(21) Appl. No.: 13/302,954

(22) Filed: Nov. 22, 2011

(30) Foreign Application Priority Data
Aug. 8, 2011 (TW) 100128260

(51) Int. Cl. G01R 1/067

(52) U.S. Cl. 324/755.01

(57) ABSTRACT

A probe assembly includes probe heads, a first connector, and groups of second connectors. Each probe head includes a first connection portion defining two first holes, and a data cable connected to an oscilligraph. The first connector includes a fixing portion and groups of rods fixed to the fixing portion. Each group of rods includes two rods. First ends of each group of rods are detachably inserted into the first holes to electrically connect the corresponding data cable. Each group of second connectors includes a second connection portion defines two second holes, and a connection cable. Second ends of the group of rods are detachably inserted into the second holes to connect the connection cable.

### TECHNICAL FIELD

The present disclosure relates to a probe assembly.

### DESCRIPTION OF RELATED ART

In electrical measurements, two probes are used. One probe is considered a positive probe and the other probe is considered the negative probe. In test, the positive probe is connected to a test point through a cable. The negative probe is connected to a ground point through another cable. If many test points are to be tested, the positive probe needs to be connected to the test points thought many cables. Therefore, it is disorderly to have so many cables, and the cables may easily lead to a short circuit.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present disclosure. Moreover, in the drawings, all the views are schematic, and like reference numerals designate corresponding parts throughout the several views.

FIG. 1 is a schematic view of an exemplary embodiment of a probe assembly.

FIG. 2 shows the probe assembly of FIG. 1 in test.

### DETAILED DESCRIPTION

The disclosure, including the accompanying drawings in which like references indicate similar elements, is illustrated by way of example and not by way of limitation. It should be noted that references to “an” or “one” embodiment in this disclosure are not necessarily to the same embodiment, and such references mean at least one.

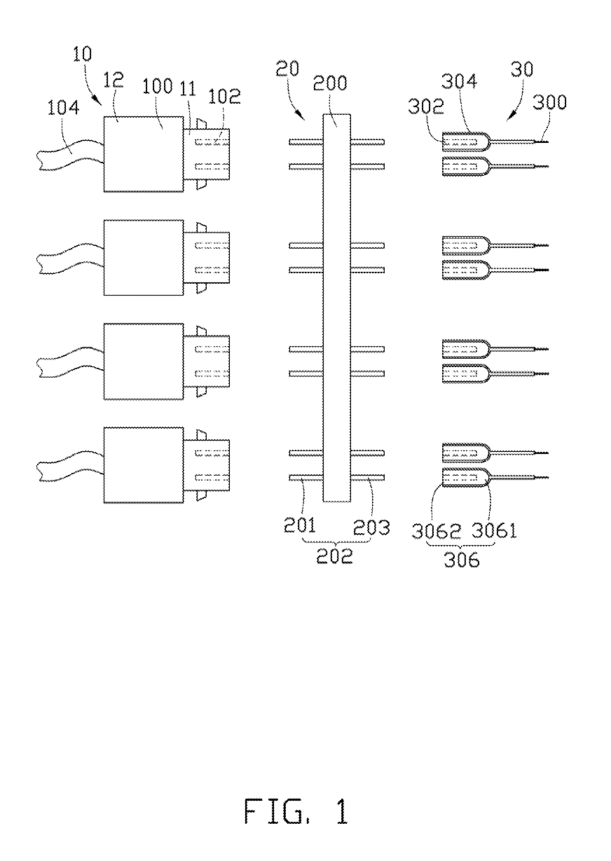

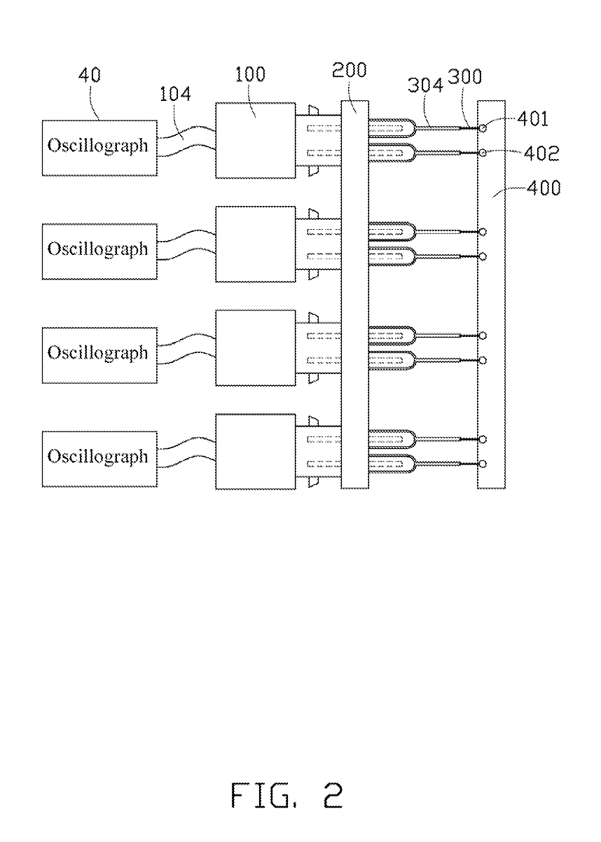

Referring to the FIGS. 1 and 2, an embodiment of a probe assembly includes a plurality of probe heads 10, a first connector 20, and a plurality of groups of second connectors 30.

Each probe head 10 includes a main body 100, a connection portion 11 extending from a first end of the main body 100, and a data cable 104 extending from a second end 12 opposite to the first end of the main body 100. Two first holes 102 are defined in the connection portion 11. The data cable 104 is connected to an oscillograph 40.

The first connector 20 includes a bar-shaped fixing portion 200 and a plurality of groups of rods perpendicularly fixed to the fixing portion 200. Each group of rods includes two rods 202. First and second ends 201 and 203 of each rod 202 respectively extend out of opposite sides of the fixing portion 200. Every two rods 202 of each rod group defines a first distance. Every two adjacent groups of rods defines a second distance. The second distance is greater than the first distance.

Each group of second connectors include two second connectors 30. Each second connector 30 includes a connection portion 306, an insulating portion 304 is wrapped around the connection portion 306, and a connection cable 300 extending out of a first end 3061 of the connection portion 306. The insulating portion 304 also wraps a part of the connection cable 300 adjacent to the connection portion 306. Two second holes 302 are defined in a second end 3062 of the connection portion 306 opposite to the first end 3061. The connection cable 300 is used to connect a plurality of test points 401 or a plurality of ground points 402 of a board 400.

In use, the first ends 201 of each group of rods are detachably inserted into the corresponding first holes 102 of the corresponding probe head 10 to connect the corresponding data cable 104. The second ends 203 of each group of rods are detachably inserted into the corresponding second holes 302 of the corresponding group of second connectors 30 to connect the corresponding connection cables 300. Distal ends of the connection cables 300 of each group of second connectors 30 are respectively connected to the corresponding test point 401 and ground point 402. Therefore, signals from the test points 401 are transmitted to the corresponding oscillograph 40 through the corresponding connection cables 300, the corresponding rods 202, and the corresponding data cables 104.

Although numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A probe assembly to test signals from test points, the probe assembly comprising:
a plurality of probe heads, each probe head comprising a main body, a first connection portion extending from the main body, and a data cable extending out from the main body to connect an oscillograph, the first connection portion defines two first holes;
a first connector comprising a fixing portion and a plurality of groups of rods fixed to the fixing portion, wherein each group of rods comprise two rods, first and second ends of each rod respectively extend out of opposite sides of the fixing portion, the first ends of each group of rods are detachably inserted into the first holes of the corresponding probe head to electrically connect the corresponding data cable; and
a plurality of group of second connectors, each group of second connectors comprising a second connection portion and a connection cable extending out of a first end of the main body to connect the corresponding test points, wherein the second connection portion defines two second holes, second ends of each group of rods are detachably inserted into the second holes to electrically connect the connection cable.

2. The probe assembly of claim 1, wherein an insulating portion is wrapped around each second connection portion and a part of the corresponding connection cable adjacent to the second connection portion.
